(19) United States
(12) Patent Application Publication
(10) Pub. No.: US 2026/0261275 A1
(43) Pub. Date: Sep. 3, 2026

(54) RECEPTION DEVICE AND COMMUNICATION DEVICE INCLUDING THE SAME

(71) Applicant: Murata Manufacturing Co., Ltd., Nagaokakyo-shi (JP)

(72) Inventors: Kenji TAHARA, Nagaokakyo-shi (JP); Kae YAMAMOTO, Nagaokakyo-shi (JP)

(21) Appl. No.: 19/660,416

(22) Filed: Apr. 28, 2026

Related U.S. Application Data
(63) Continuation of application No. PCT/JP2024/034120, filed on Sep. 25, 2024.

(30) Foreign Application Priority Data
Nov. 8, 2023 (JP) 2023-190708

(51) Int. Cl. H04B 1/00; H04B 1/40

(52) U.S. Cl. CPC H04B 1/006; H04B 1/40

(57) ABSTRACT

A reception device receives a radio frequency signal via an antenna. The reception device includes first and second paths, a switch circuit, a first substrate, and a second substrate disposed on the first substrate. The first path extracts information from a received radio frequency signal. The second path extracts power from a received radio frequency signal. The switch circuit distributes a received radio frequency signal to the first and second paths. The first substrate is an Si-based semiconductor substrate. The second substrate is a semiconductor substrate containing a compound of group-III and group-V elements. The first path includes a reception module. The second path includes a rectifier circuit. The switch circuit and the reception module are disposed in the first substrate, and the rectifier circuit is disposed in the second substrate.

### CROSS-REFERENCE TO RELATED APPLICATIONS

This is a continuation of International Application No. PCT/JP2024/034120 filed on September 25, 2024 which claims priority from Japanese Patent Application No. 2023-190708 filed on November 8, 2023. The contents of these applications are incorporated herein by reference in their entireties.

### BACKGROUND OF THE DISCLOSURE

### Field of the Disclosure

The present disclosure relates to a reception device and a communication device including the same and, more particularly, to wireless power transfer using radio frequency signals.

### Description of the Related Art

International Publication No. 2019/097806 discloses a rectifying device for converting microwave wireless power to direct current power, and a rectenna apparatus. The rectenna apparatus disclosed in International Publication No. 2019/097806 enables wireless power transfer (WPT) over relatively long distances using microwaves.

### BRIEF SUMMARY OF THE DISCLOSURE

In recent years, as mobile communication devices, such as cellular phones and smartphones, advance and IoT devices, such as vehicles and electrical devices each having communication functions, become widespread, communication traffic in mobile communication systems is significantly increasing. As communication traffic increases, capital expenditure and operating costs also increase. Thus, to achieve high performance and cost efficiency, power consumption and cost per unit of communication speed have to be reduced. Hence, further reductions in power consumption and cost of networks and terminal devices in communication systems are necessary.

Furthermore, particularly in mobile devices, batteries in the devices have to be charged. As a method of supplying power to these devices, contactless wireless power transfer is being developed. In wireless power transfer, in general, power transfer is performed by electromagnetic induction or electromagnetic resonance by bringing a device to be charged close to a predetermined power transfer device.

A large amount of radio wave energy is present in everyday environments; however, unlike other forms of energy such as thermal energy and optical energy, radio wave energy is less affected by natural environmental conditions. Radio wave energy has an advantage of being present and stable at any time of day or night and indoors or outdoors. Hence, using such radio wave energy as power can suppress an increase in the amount of power generation demanded and also mitigate the costs involved in further improving power transfer efficiency for devices.

The present disclosure has been made to address such issues and aims to efficiently perform wireless power transfer using radio waves for information communication in a reception device used in a communication device.

A reception device according to the present disclosure receives a radio frequency signal via an antenna. The reception device includes a first path, a second path, a distribution circuit, a first substrate, and a second substrate disposed on the first substrate. The first path is configured to extract information from a received radio frequency signal. The second path is configured to extract power from a received radio frequency signal. The distribution circuit distributes a received radio frequency signal to the first path and the second path. The first substrate is a semiconductor substrate containing a material primarily composed of an Si-based base material. The second substrate is a semiconductor substrate containing a material primarily composed of a compound of group-III and group-V elements. The first path includes a reception module having an amplifier circuit that amplifies a radio frequency signal. The second path includes a rectifier circuit that rectifies a radio frequency signal. The distribution circuit and the reception module are disposed in the first substrate, and the rectifier circuit is disposed in the second substrate.

In the reception device according to the present disclosure, a radio frequency signal received by the antenna is distributed to two paths (first path, second path), information can be extracted from the radio frequency signal in the first path, and power can also be extracted from the radio frequency signal in the second path. The rectifier circuit included in the second path for power extraction is formed on the semiconductor substrate containing a material primarily composed of a compound of group-III and group-V elements (hereinafter also referred to as “group III-V compound”). In general, group III-V compounds have a higher power density than Si-based materials used for existing semiconductor substrates. This enables significant loss reduction compared to semiconductors made of Si-based materials, thus reducing conversion losses in the rectifier circuit. Hence, the reception device according to the present disclosure enables efficient wireless power reception using radio waves for information communication.

### BRIEF DESCRIPTION OF THE SEVERAL VIEWS OF THE DRAWINGS

FIG. 1 is an overall block diagram of a communication device in which a reception device according to Embodiment 1 is used.

FIG. 2 is a diagram illustrating the layout of circuits of the reception device on a substrate.

FIG. 3 is a side cutaway view of the substrate illustrated in FIG. 2.

FIG. 4 is a side cutaway view illustrating an example of mounting of a communication module.

FIG. 5 is a diagram illustrating respective timings at which communication processing and power reception processing are performed in the communication device.

FIG. 6 is a flowchart illustrating control performed in the communication device.

FIG. 7 is a graph illustrating an example of gain and bias voltage settings based on the received signal levels of radio frequency signals.

FIG. 8 is a side cutaway view of a substrate where a reception device in a modification is formed.

FIG. 9 is an overall block diagram of a communication device in which a reception device according to Embodiment 2 is used.

### DETAILED DESCRIPTION OF THE DISCLOSURE

Embodiments of the present disclosure will be described in detail below with reference to the drawings. Note that identical or corresponding elements or portions in the drawings are denoted by the same reference signs and no repeated description thereof is provided.

### Embodiment 1

### Configuration of Communication Device

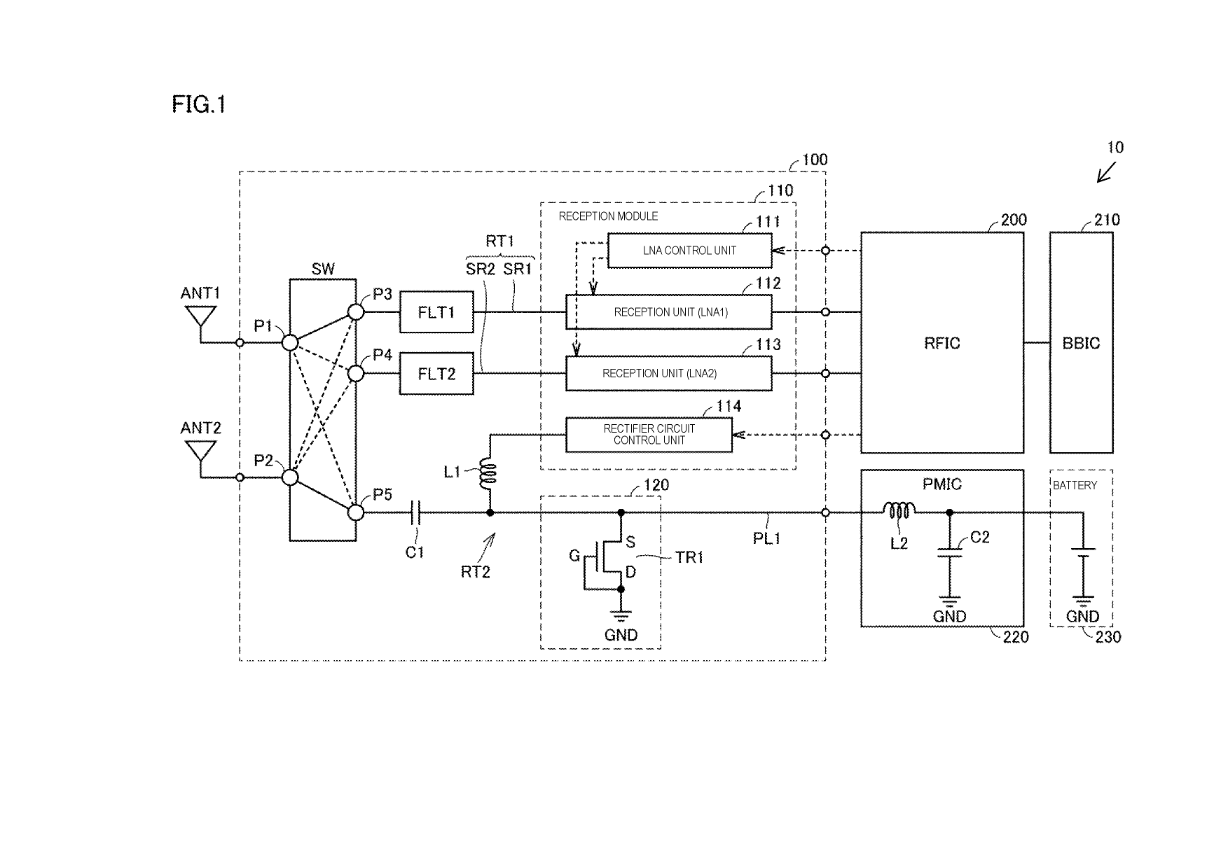

FIG. 1 is an overall block diagram of a communication device 10 in which a reception device 100 according to Embodiment 1 is used. The communication device 10 includes, in addition to the reception device 100, antennas ANT1 and ANT2, an RFIC 200, a BBIC 210, a PMIC 220, and a battery 230. In outline, the communication device 10 processes radio frequency signals received by the antennas ANT1 and ANT2 using the RFIC 200 and the BBIC 210 to extract information contained in the radio frequency signals. Furthermore, the communication device 10 rectifies received radio frequency signals to extract power from the radio frequency signals and charges the battery 230 using the extracted power.

The reception device 100 includes a switch circuit SW, filters FLT1 and FLT2, a reception module 110, a rectifier circuit 120, a capacitor C1, and an inductor L1. Furthermore, the reception module 110 includes an LNA control unit 111, reception units 112 and 113, and a rectifier circuit control unit 114.

The switch circuit SW distributes radio frequency signals received from the antennas ANT1 and ANT2 to a path RT1 (first path) that extracts information and a path RT2 (second path) that extracts power. In the reception device 100 according to Embodiment 1, the path RT1 further includes two sub-paths corresponding to frequencies of signals to be extracted. In addition, the number of sub-paths included in the path RT1 may be one, or may be three or more.

The switch circuit SW includes input terminals P1 and P2, and output terminals P3, P4, and P5. The antennas ANT1 and ANT2 are respectively connected to the input terminals P1 and P2. A sub-path SR1, which is one sub-path of the path RT1, is connected to the output terminal P3, and a sub-path SR2, which is the other sub-path of the path RT1, is connected to the output terminal P4. The path RT2 is connected to the output terminal P5.

The switch circuit SW outputs a radio frequency signal received at the input terminal P1 to any of the output terminals P3, P4, and P5. Furthermore, the switch circuit SW outputs a radio frequency signal received at the input terminal P2 to any of the output terminals P3, P4, and P5. When information is to be extracted from a received radio frequency signal, the switch circuit SW is switched to output the radio frequency signal from the output terminal P3 or the output terminal P4. On the other hand, when power is to be extracted from a received radio frequency signal, the switch circuit SW is switched to output the radio frequency signal from the output terminal P5. Radio frequency signals from the input terminals P1 and P2 may be outputted to the same output terminal, or may be outputted to respective different output terminals.

In the sub-path SR1, the output terminal P3 is connected to the reception unit 112 in the reception module 110 via the filter FLT1. The filter FLT1 is, for example, a band pass filter that passes a signal in a specified frequency band. The filter FLT1 extracts signals in a desired frequency band from radio frequency signals received at the antennas ANT1 and ANT2 and outputs the extracted signals to the reception unit 112. The reception unit 112 includes a low noise amplifire (LNA). In addition, the LNA included in the reception unit 112 is also referred to as “LNA1”. The reception unit 112 amplifies radio frequency signals that have passed through the filter FLT1 with low noise and outputs the radio frequency signals to the RFIC 200.

Similarly, in the sub-path SR2, the output terminal P4 is connected to the reception unit 113 in the reception module 110 via the filter FLT2. As with the filter FLT1, the filter FLT2 is also a band pass filter. A passband of the filter FLT2 may be the same as or different from a passband of the filter FLT1. The filter FLT2 extracts signals in a desired frequency band from radio frequency signals received at the antennas ANT1 and ANT2 and outputs the extracted signals to the reception unit 113. The reception unit 113 amplifies radio frequency signals that have passed through the filter FLT2 with a low noise amplifier LNA2 and outputs the radio frequency signals to the RFIC 200.

The RFIC 200 down-converts radio frequency signals received from the sub-paths SR1 and SR2 to an intermediate frequency and outputs the signals to the BBIC 210. In the BBIC 210, the signals received from the RFIC 200 are processed, and information (for example, audio signals) contained in the signals is extracted.

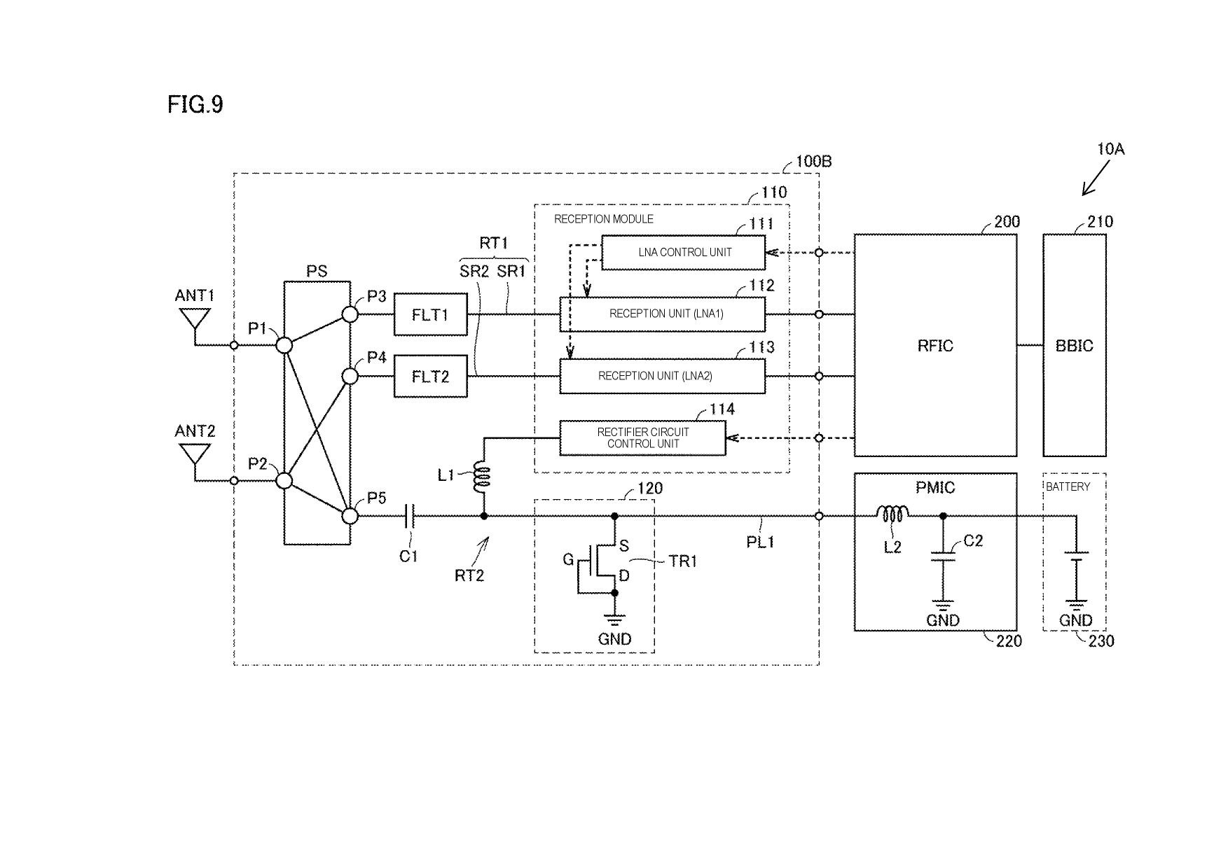

The RFIC 200 detects received signal levels of radio frequency signals received from the sub-paths SR1 and SR2 and outputs these levels to the LNA control unit 111 included in the reception module 110. The LNA control unit 111 adjusts an LNA gain in accordance with information on a received signal level received from the RFIC 200. In outline, the LNA control unit 111 sets the gain to a higher value as the received signal level decreases. The gain adjusted by the LNA control unit 111 may be varied continuously and linearly, or the gain may be varied stepwise as described later with reference to FIG. 9. As described above, adjusting the LNA gain in accordance with a received signal level can stabilize the received signal level of a radio frequency signal transmitted to the RFIC 200.

In the path RT2, the capacitor C1 for direct current (DC) blocking is connected to the output terminal P5 of the switch circuit SW. The capacitor C1 is connected to the PMIC 220 via a transmission line PL1.

Furthermore, the rectifier circuit 120 is connected to the transmission line PL1. The rectifier circuit 120 rectifies an alternating current (AC) waveform of a radio frequency signal that has passed through the capacitor C1 into a DC signal. The PMIC 220 includes a low pass filter constituted by an inductor L2 and a capacitor C2. The rectified DC signal from the rectifier circuit 120 is smoothed by the low pass filter included in the PMIC 220 and is outputted to the battery 230. The battery 230 is charged using the DC signal output from the PMIC 220 as charging power. In addition, although not illustrated in FIG. 1, the PMIC 220 may include a DC/DC converter that converts a voltage level of a rectified DC signal to a voltage suitable for charging the battery 230.

In an example of the reception device 100 illustrated in FIG. 1, the rectifier circuit 120 includes a transistor TR1 including a source terminal S, a drain terminal D, and a gate terminal G. The source terminal S of the transistor TR1 is connected to the transmission line PL1, and the drain terminal D is connected to a ground potential GND. The drain terminal D is also connected to the gate terminal G. That is, the transistor TR1 functions as a gated anode diode having a cathode connected to the transmission line PL1 and an anode connected to the ground potential GND. Thus, a radio frequency signal that has passed through the capacitor C1 is half-wave rectified into a DC signal.

Furthermore, a bias voltage is supplied from the rectifier circuit control unit 114 of the reception module 110 to the transmission line PL1 in the path RT2 via the inductor L1. The rectifier circuit control unit 114 adjusts a bias voltage supplied to the transmission line PL1 in accordance with information on a received signal level transmitted from the RFIC 200. Specifically, the rectifier circuit control unit 114 sets the bias voltage to a lower value as the received signal level increases. In other words, the rectifier circuit control unit 114 sets a higher bias voltage when the received signal level is low.

The transistor TR1 functioning as a gated anode diode operates when the voltage between the source terminal S and the drain terminal D is not less than a predetermined value. For this reason, the rectifier circuit control unit 114 sets a higher bias voltage when the received signal levels of radio frequency signals received by the antennas ANT1 and ANT2 are low, thereby enabling the transistor TR1 to operate.

Note that the rectifier circuit 120 is not limited to the above-described configuration as long as the rectifier circuit 120 can convert an AC signal to a DC signal. The rectifier circuit 120 may be, for example, a Schottky diode, a diode bridge, or an AC/DC converter including an active switching element.

As described above, in the reception device 100 according to Embodiment 1, transmission paths for radio frequency signals received by the antennas ANT1 and ANT2 are switched by the switch circuit SW, thereby enabling extraction of information and power from the radio frequency signals. That is, in the reception device 100, power can be wirelessly received using radio frequency signals (radio waves) used for communication.

A large amount of radio wave energy is present in everyday environments; however, unlike other forms of energy such as thermal energy and optical energy, radio wave energy is less affected by natural environmental conditions. Furthermore, radio waves in frequency bands that are no longer in use may still be radiated into an environment. In the reception device 100 according to Embodiment 1, radio wave energy that is present and stable at any time of day or night and indoors or outdoors can be used as power, thus making it possible to suppress an increase in the amount of power generation demanded and also mitigate the costs involved in further improving power transfer efficiency for the device.

In general wireless communication, a method of switching between transmission and reception in a time-division manner is used in many cases. A circuit in the path RT1 that extracts information operates at predetermined intervals. For this reason, power is received using a circuit in the path RT2 in an interval period during which operation of the path RT1 is interrupted, thereby making it possible to charge the device without interfering with information communication.

Furthermore, information extraction and power extraction do not necessarily have to be alternately performed. For example, a radio frequency signal received by the antenna ANT1 is used as a signal for information extraction, a radio frequency signal received by the antenna ANT2 is used as a signal for power extraction, and thus information extraction and power extraction can be performed simultaneously at all times. In this case, however, attention is paid to the possibility that the received signal level of a received signal transmitted to each path may be halved, the quality of the received signal may be degraded, and/or sufficient received power may be unable to be obtained.

Here, using a semiconductor with high electric power handling capability and low loss for the transistor TR1 constituting the rectifier circuit 120 enables highly efficient power conversion. As a material of such a low-loss semiconductor, there is a material primarily composed of a compound of group-III and group-V elements (hereinafter also referred to as “group III-V compound”), such as gallium nitride (GaN), gallium arsenide (GaAs), or indium phosphide (InP). Such a material has a higher power density than Si-based materials that have been used in the art, thus enabling significant loss reduction compared to semiconductors made of Si-based materials.

On the other hand, in general, group III-V compounds are expensive compared to Si-based materials. Thus, when all circuits constituting the reception device 100 are formed of a group III-V compound, the overall cost of the device may be increased. Hence, in Embodiment 1, only a rectifier circuit 120 portion where low loss and high efficiency are particularly demanded is formed of a group III-V compound, and the other circuit portions are formed in an Si-based substrate, thereby enabling an improvement in circuit efficiency while suppressing an increase in cost.

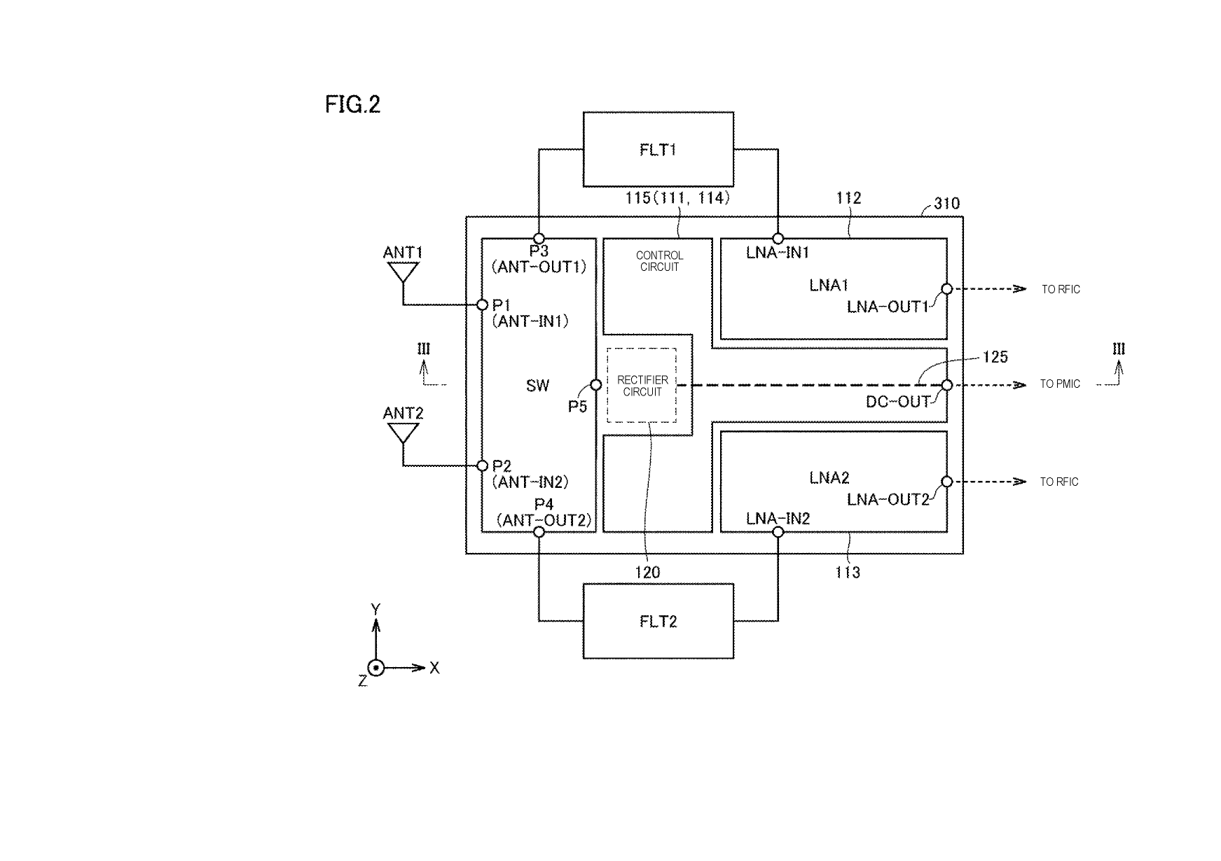

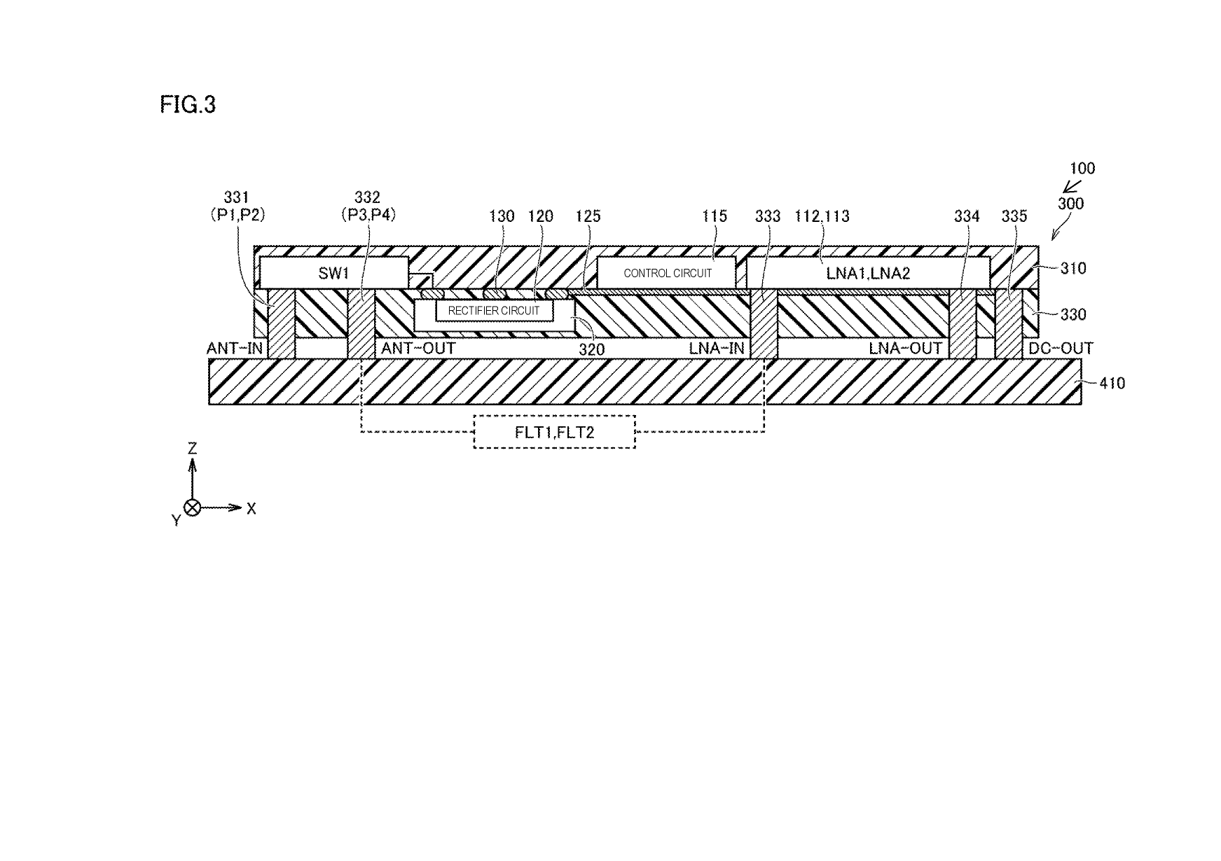

Next, the layout of circuits of the reception device 100 on a substrate will be described with reference to FIGS. 2 and 3. FIG. 2 is a diagram illustrating the layout of circuits of the reception device 100 on a substrate 300. Furthermore, FIG. 3 is a side cutaway view of the substrate 300 taken along line III-III in FIG. 2.

In FIGS. 2 and 3, the substrate 300 has a substantially rectangular flat-plate shape. The substrate 300 is described with a direction normal to the substrate 300 defined as a Z-axis, a direction along the long side of the substrate 300 defined as an X axis, and a direction along the short side defined as a Y axis. In addition, a positive direction of a Z axis may be referred to as an upward direction, and a negative direction as a downward direction.

As illustrated in FIG. 3, the substrate 300 includes two different substrates 310 and 320, and a resin 330 for encapsulation. The substrate 310 is a semiconductor substrate made of an Si-based material, where the switch circuit SW, a control circuit 115, and the reception units 112 and 113 including the respective LNAs in FIG. 1 are formed. The control circuit 115 and the reception units 112 and 113 constitute the reception module 110. The substrate 310 is disposed on a mounting substrate 410 using a plurality of connection electrodes 331 to 335.

The substrate 320 is a substrate made of a material composed of a group III-V compound, such as GaN, where the rectifier circuit 120 in FIG. 1 is formed. The substrate 320 is mounted on a lower surface of the substrate 310. The lower surface of the substrate 310 is molded with the resin 330 such that the resin 330 covers the substrate 320.

As illustrated in FIG. 2, the switch circuit SW in FIG. 1 is disposed in a region of an end portion (first end portion) of the substrate 310 in a negative X-axis direction. The switch circuit SW is connected to the antennas ANT1 and ANT2 via the connection electrode 331 (ANT-IN). Furthermore, the switch circuit SW is connected to the filters FLT1 and FLT2 disposed outside the substrate 300 via the connection electrode 332 (ANT-OUT).

The control circuit 115 including the LNA control unit 111 and the rectifier circuit control unit 114 in the reception module 110 is disposed in a region in a positive X-axis direction with respect to the switch circuit SW in the substrate 310. The region of the control circuit 115 is substantially Y-shaped as a whole, and a portion thereof extends to near an end portion (second end portion) of the substrate 310 in the positive X-axis direction.

The substrate 320 where the rectifier circuit 120 is formed is mounted, using a solder bump 130, on a lower surface side of a space portion between the control circuit 115 and the switch circuit SW around the middle of the substrate 310 in a Y-axis direction. For the purpose of loss reduction in the power transmission path (path RT2), the rectifier circuit 120 is disposed at a position closer to the switch circuit SW than to the control circuit 115 and the LNA1 and LNA2.

A signal from the switch circuit SW is transmitted to the rectifier circuit 120 via the solder bump 130. An output signal from the rectifier circuit 120 is transmitted to the connection electrode 335 on an end portion side of the substrate 310 in the positive X-axis direction via a wiring pattern 125 disposed on the lower surface of the substrate 310. The signal transmitted to the connection electrode 335 (DC-OUT) is transmitted to the battery 230 via the PMIC 220.

The substrate 320 including the rectifier circuit 120 is disposed on the lower surface side of the substrate 310, and no other circuit is formed in a portion of the substrate 310 corresponding to the position of the rectifier circuit 120, thereby enabling improved heat dissipation efficiency from the rectifier circuit 120.

In a region near the end portion (second end portion) of the substrate 310 in the positive X-axis direction, in end portions in the Y-axis direction, the reception units 112 and 113 including the respective LNA1 and LNA2 are disposed with part of the control circuit 115 interposed therebetween. More specifically, the reception unit 112 is disposed in a region near an end portion in a positive Y-axis direction, and the reception unit 113 is disposed in a region near an end portion in a negative Y-axis direction. The part of the control circuit 115 is disposed in a region between the reception unit 112 and the reception unit 113.

The filters FLT1 and FLT2 are respectively connected to the reception units 112 and 113 via the connection electrode 333 (LNA-IN). Furthermore, the reception units 112 and 113 are connected to the RFIC 200 via the connection electrode 334 (LNA-OUT).

The LNA1 and LNA2 included in the reception units 112 and 113 are relatively sensitive to temperature, and characteristics thereof tend to vary due to temperature changes. On the substrate 310, the reception units 112 and 113 are disposed with the control circuit 115 interposed therebetween and spaced apart from the rectifier circuit 120, which is prone to heat generation, thereby enabling reduction in thermal influence on the reception units 112 and 113.

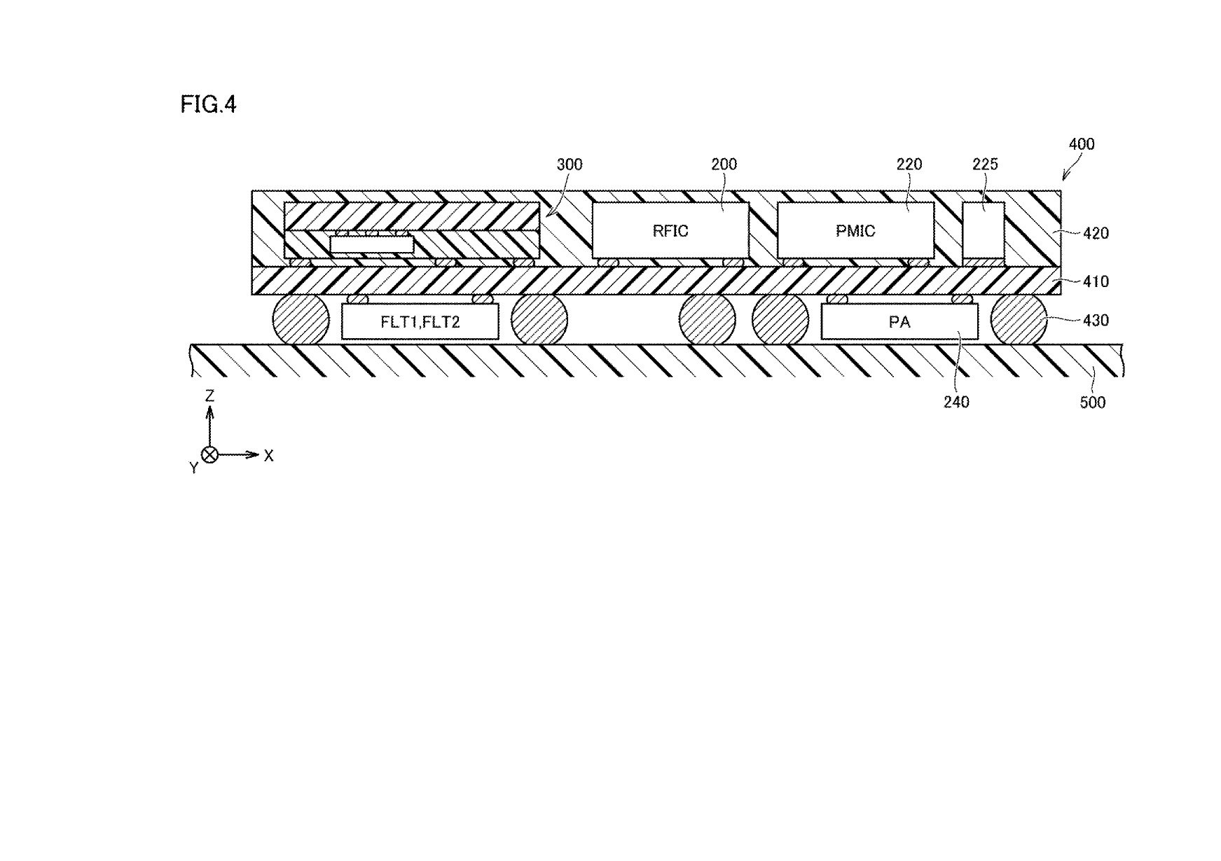

FIG. 4 is a side cutaway view illustrating an example of mounting of a communication module 400. In FIG. 4, on an upper surface of the mounting substrate 410, the substrate 300 where the reception device 100 is formed, the RFIC 200, the PMIC 220, and a power inductor 225 are mounted. Additionally, on a lower surface of the mounting substrate 410, the filters FLT1 and FLT2 and a power amplifier 240 are mounted. The circuits on an upper surface side of the mounting substrate 410 are molded with a resin 420 for encapsulation. In addition, the circuits on a lower surface side of the mounting substrate 410 may be similarly molded. The communication module 400 is mounted on a base substrate 500 using a solder ball 430.

As described above, the rectifier circuit 120 where high efficiency and low loss are demanded is formed in a semiconductor substrate using a group III-V compound as a base material, and the other circuits of the reception device 100 are formed in a semiconductor substrate composed of an Si-based material, thereby enabling an improvement in circuit efficiency while suppressing an increase in cost. Furthermore, when each circuit on the substrate is disposed as illustrated in FIG. 2, heat dissipation efficiency can be improved, and thermal influence on the LNAs can be reduced.

### Control Method of Communication Device

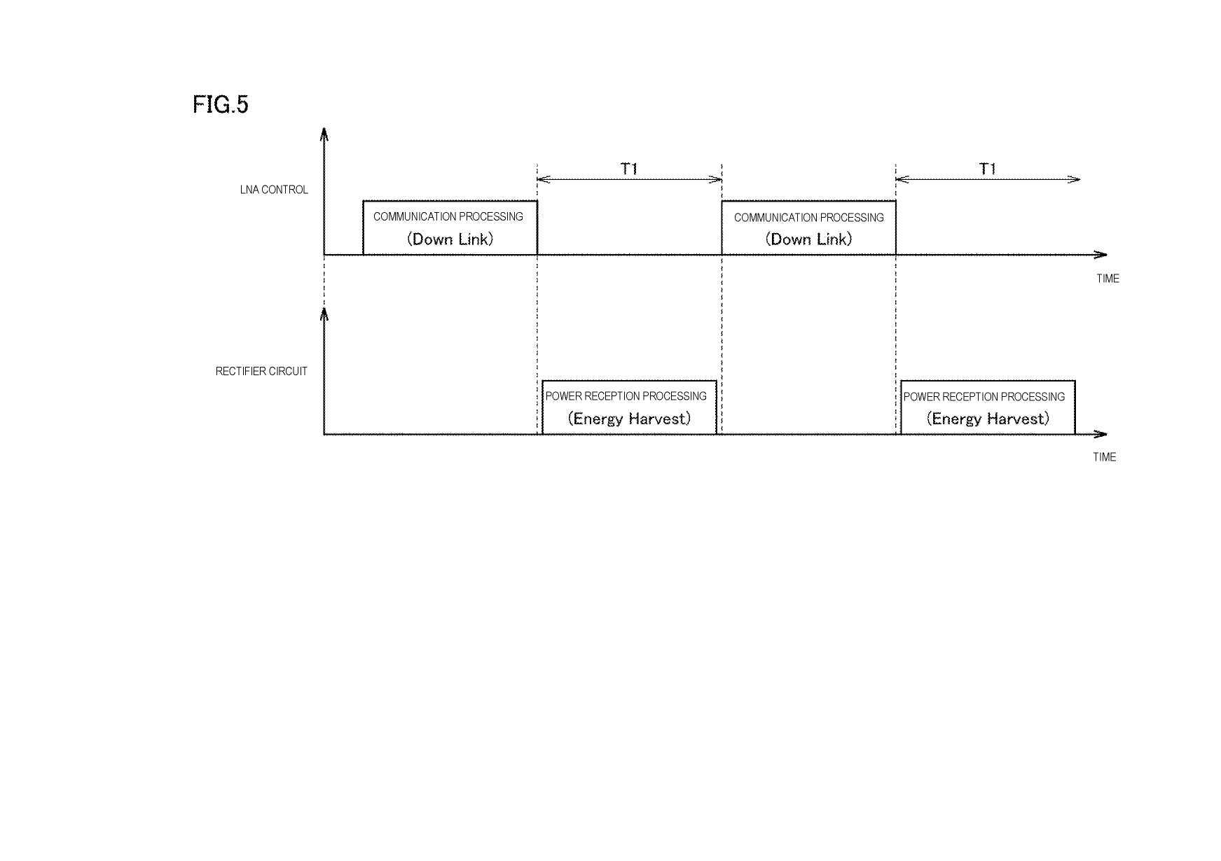

Next, an overview of a control method in the communication device 10 will be described with reference to FIGS. 5 to 7.

First, respective timings at which communication processing and power reception processing are performed in the communication device 10 will be described with reference to FIG. 5. In FIG. 5, an upper section illustrates a timing at which communication processing is performed by an LNA in the path RT1, and a lower section illustrates a timing at which power reception processing is performed by the rectifier circuit 120 in the path RT2.

In communication devices, time division duplex (TDD) is generally used, in which communication is performed between a base station and a terminal device while transmission and reception are alternately switched in time. Thus, communication processing (Down Link) for extracting information from a received signal in a reception device is performed at predetermined intervals T1 as illustrated in the upper section in FIG. 5.

The reception device 100 according to Embodiment 1 performs power reception processing (Energy Harvest) of extracting power from a received signal by switching the switch circuit SW to the path RT2 in a period during which communication processing in the path RT1 is interrupted. Through such a process, power can be extracted from radio waves in an environment without interfering with existing information communication processing.

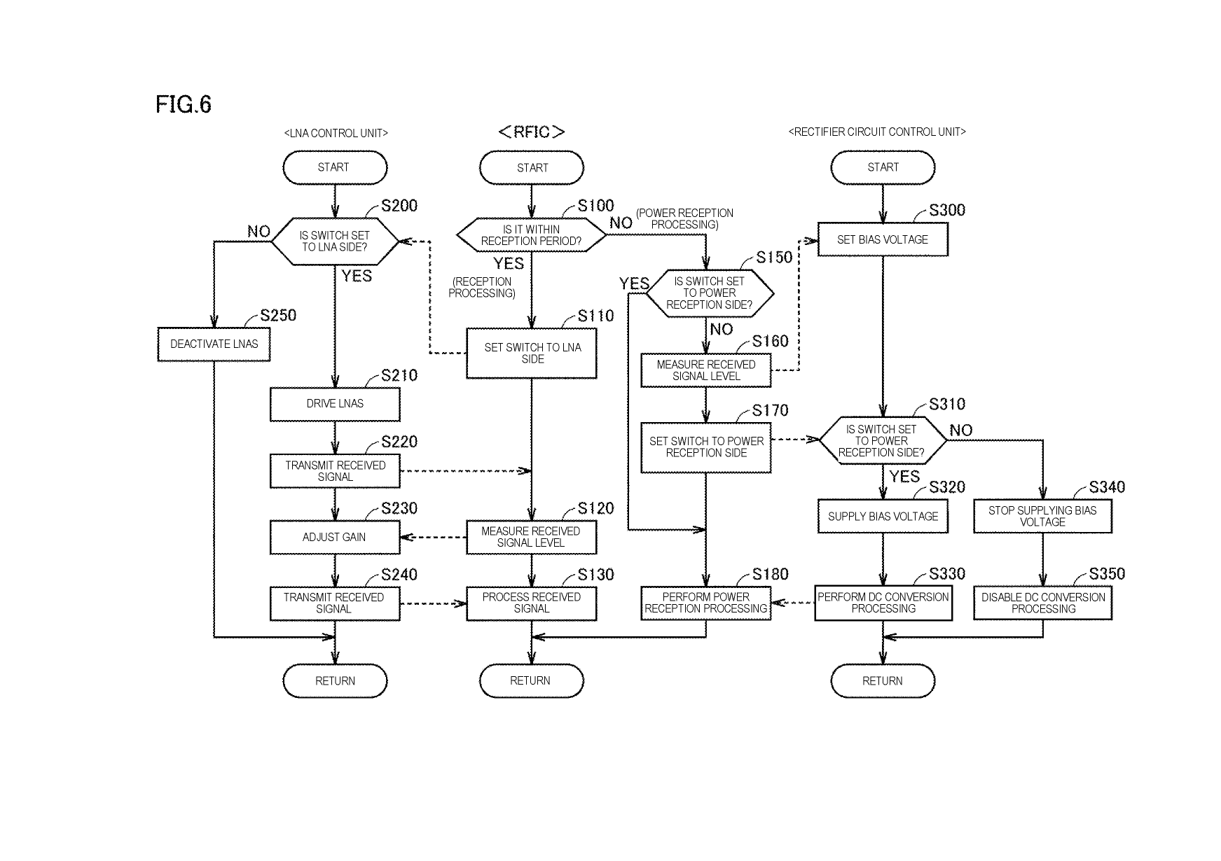

FIG. 6 is a flowchart illustrating control performed in the communication device 10. FIG. 6 illustrates a flowchart of control in the LNA control unit 111, the RFIC 200, and the rectifier circuit control unit 114.

First, a process in the RFIC 200 will be described. The RFIC 200 determines in step (hereinafter step is abbreviated as S) 100 whether it is within a reception period during which communication processing is to be performed. When it is within the reception period (YES in S100), the RFIC 200 proceeds to S110 to switch the switch circuit SW to the path RT1 on an LNA side. If the switch circuit SW is already set to the path RT1, the switch circuit SW1 remains in that state. The setting state of the switch circuit SW is outputted to the LNA control unit 111.

When the switch circuit SW is switched to the LNA side, the LNAs are driven by the LNA control unit 111, and a received radio frequency signal is outputted to the RFIC 200.

Then, the RFIC 200 measures a received signal level in accordance with the strength of the received radio frequency signal in S120 and outputs a measurement value to the LNA control unit 111. In the LNA control unit 111, an LNA gain is set in accordance with the received signal level from the RFIC 200.

Subsequently, the RFIC 200 processes a received signal transmitted from the reception unit 112 or 113 in S130 and outputs the signal to the BBIC 210.

On the other hand, when it is determined in S100 that it is not within the reception period (NO in S100), the RFIC 200 proceeds to S150 to determine whether the current state of the switch circuit SW is set to the path RT2 on a power reception side.

When the switch circuit SW is not set to the path RT2 (NO in S150), that is, when the switch circuit SW is set to the path RT1, the RFIC 200 proceeds to S160 to measure a current received signal level and outputs it to the rectifier circuit control unit 114. In the rectifier circuit control unit 114, a bias voltage to the rectifier circuit 120 is set in accordance with the received signal level from the RFIC 200.

Subsequently, the RFIC 200 switches the switch circuit SW to the path RT2 (S170) and performs power reception processing using the rectifier circuit 120 (S180).

Next, a process in the LNA control unit 111 will be described. The LNA control unit 111 determines in S200, in accordance with a signal from the RFIC 200, whether the current state of the switch circuit SW is set to the path RT1 on the LNA side. When the switch circuit SW is not set to the LNA side (NO in S200), that is, when the switch circuit SW is set to the power reception side, the LNA control unit 111 proceeds to S250 to deactivate the LNAs of the reception units 112 and 113.

When the switch circuit SW is set to the LNA side (YES in S200), the LNA control unit 111 drives the LNAs of the reception units 112 and 113 in S210. If the LNAs are already in a state in which they are driven, the LNAs remain in that state. When the LNAs are driven, a received signal is transmitted to the RFIC 200 (S220). An LNA gain at this time is set to a predetermined default value or to a gain value used last time.

As described above, in the RFIC 200, a received signal level of the received signal transmitted from the reception unit 112 or 113 is measured, and information on the measured received signal level is transmitted to the LNA control unit 111.

When the LNA control unit 111 receives the information on the received signal level from the RFIC 200, the LNA control unit 111 adjusts the LNA gain in accordance with the received signal level (S230). Specifically, the LNA control unit 111 sets the LNA gain to a higher value as the received signal level decreases. In response to this, the reception unit 112 or 113 transmits a received signal amplified using the adjusted gain to the RFIC 200 (S240). When the received signal level varies during a communication processing period, the LNA control unit 111 appropriately adjusts the LNA gain in response to the variation. Setting the gain as described above enables stabilization of the received signal level in the RFIC 200.

Finally, a process in the rectifier circuit control unit 114 will be described. The rectifier circuit control unit 114 sets a bias voltage supplied to the transmission line PL1 in S300 in accordance with the received signal level of the received signal transmitted from the RFIC 200. Specifically, the rectifier circuit control unit 114 sets the bias voltage to a lower value as the received signal level increases in a range in which the received signal level is higher than a predetermined level. In other words, a higher bias voltage is set when the received signal level is low. This maintains the voltage between the source terminal S and the drain terminal D in the transistor TR1, which functions as a gated anode diode, at a value not less than a predetermined value to enable rectification operation to be performed.

The bias voltage supplied from the rectifier circuit control unit 114 is basically a voltage to compensate for a shortfall in the operating voltage of the transistor TR1 (that is, the potential difference between the source terminal S and the drain terminal D). For this reason, if the received signal level of the received signal is too low, as a result, most of the power converted by the rectifier circuit 120 becomes power due to the bias voltage. Hence, the bias voltage is supplied by the rectifier circuit control unit 114 when the received signal level of the received signal is in the range higher than the predetermined level, and power reception processing is not performed when the received signal level is less than the predetermined level.

Subsequently, the rectifier circuit control unit 114 determines in S310, in accordance with a signal transmitted from the RFIC 200, whether the switch circuit SW is set to the path RT2 on the power reception side. When the switch circuit SW is set to the power reception side (YES in S310), the rectifier circuit control unit 114 proceeds to S320 to supply the bias voltage set in S300 to the transmission line PL1. Thus, DC conversion processing is performed in the rectifier circuit 120 (S330), and the battery 230 is charged using converted DC power.

On the other hand, when the switch circuit SW is not set to the power reception side (NO in S310), that is, when the switch circuit SW is set to the LNA side, the rectifier circuit control unit 114 stops supplying the bias voltage to the transmission line PL1 in S340. Thus, DC conversion processing by the rectifier circuit 120 is disabled (S350).

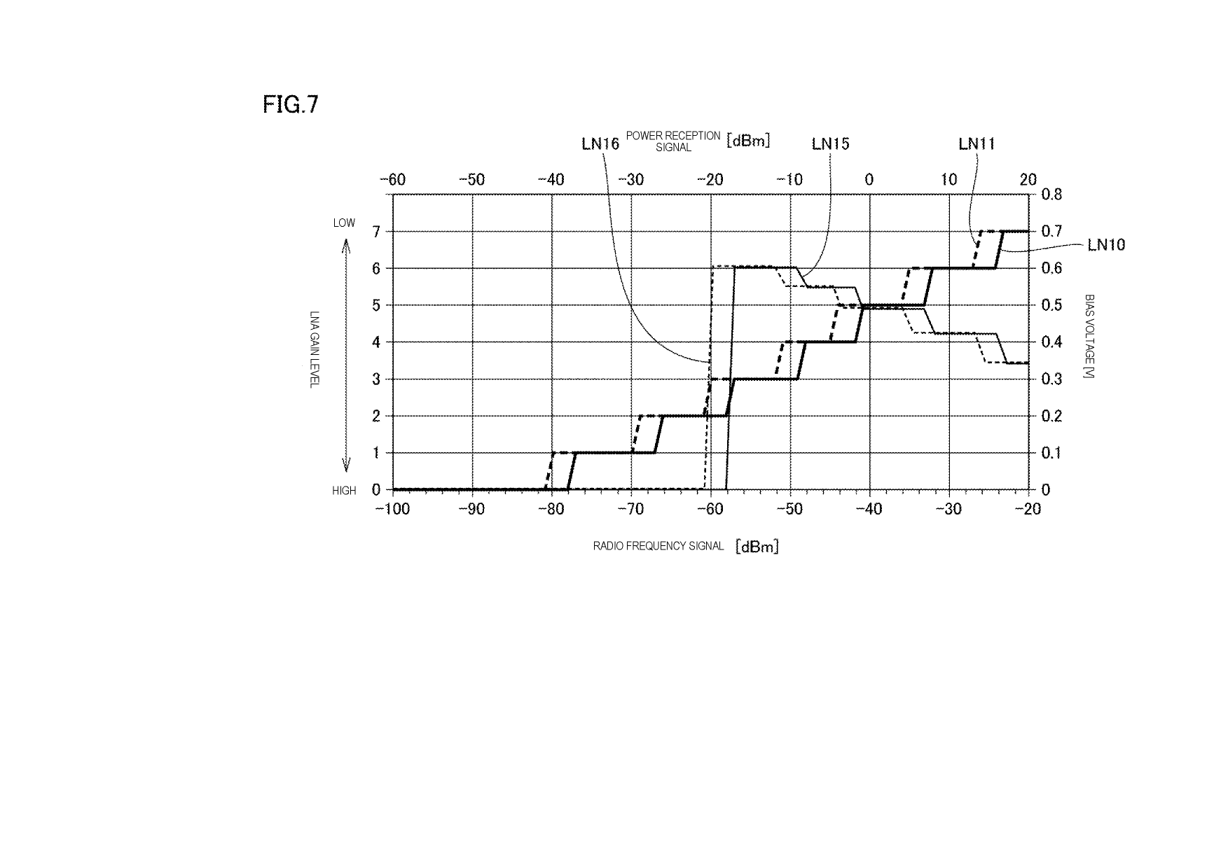

FIG. 7 is a graph illustrating an example of LNA gain and bias voltage settings based on the received signal levels of radio frequency signals. In FIG. 7, the horizontal axis represents the received signal level of the received signal, the left axis represents the LNA gain level, and the right axis represents the bias voltage. In addition, for the horizontal axis, an upper axis labeled “power reception signal” indicates the received signal level corresponding to the bias voltage, and a lower axis labeled “radio frequency signal” indicates the received signal level corresponding to the LNA gain. The LNA gain level is set to eight levels (3 bits), represented by values from 0 to 7, for example, and the gain level increases as the value indicating the state decreases.

Furthermore, in FIG. 7, lines LN10 and LN11 indicate the LAN gain, and lines LN15 and LN16 indicate the bias voltage. Solid lines LN10 and LN15 indicate transitions when the LNA gain or bias voltage increases. Dashed lines LN11 and LN16 indicate transitions when the LNA gain or bias voltage decreases. Hysteresis is provided for both the LNA gain and the bias voltage in an increasing case and a decreasing case to keep their settings from chattering in response to variations in the received signal level.

As illustrated in FIG. 7, the LNA gain set by the LNA control unit 111 is set to a lower value when the received signal level increases and to a higher value when the received signal level decreases. On the other hand, the bias voltage set by the rectifier circuit control unit 114 is, in a range higher than a predetermined received signal level (-20 dBm), reduced when the received signal level increases and increased when the received signal level decreases.

When the processes illustrated in FIG. 6 are performed in the LNA control unit 111, the RFIC 200, and the rectifier circuit control unit 114 using a configuration table such as that illustrated in FIG. 7, power can be extracted from radio waves in an environment to do the battery without interfering with information communication processing.

The “switch circuit SW” in Embodiment 1 corresponds to the “distribution circuit” in the present disclosure. The “substrate 310” and “substrate 320” in Embodiment 1 respectively correspond to the “first substrate” and “second substrate” in the present disclosure. Each of the “LNA1 and LNA2” in Embodiment 1 corresponds to the “amplifier circuit” in the present disclosure. The “source terminal S”, “drain terminal D”, and “gate terminal G” in Embodiment 1 respectively correspond to the “first terminal”, “second terminal”, and “third terminal” in the present disclosure. The “rectifier circuit control unit 114” and “LNA control unit 111” in Embodiment 1 respectively correspond to the “first control circuit” and “second control circuit” in the present disclosure. Each of the “filter FLT1 and filter FLT2” in Embodiment 1 corresponds to the “filter circuit” in the present disclosure. The “RFIC 200” and “BBIC 210” in Embodiment 1 correspond to the “signal processing circuit” in the present disclosure.

### Modifications

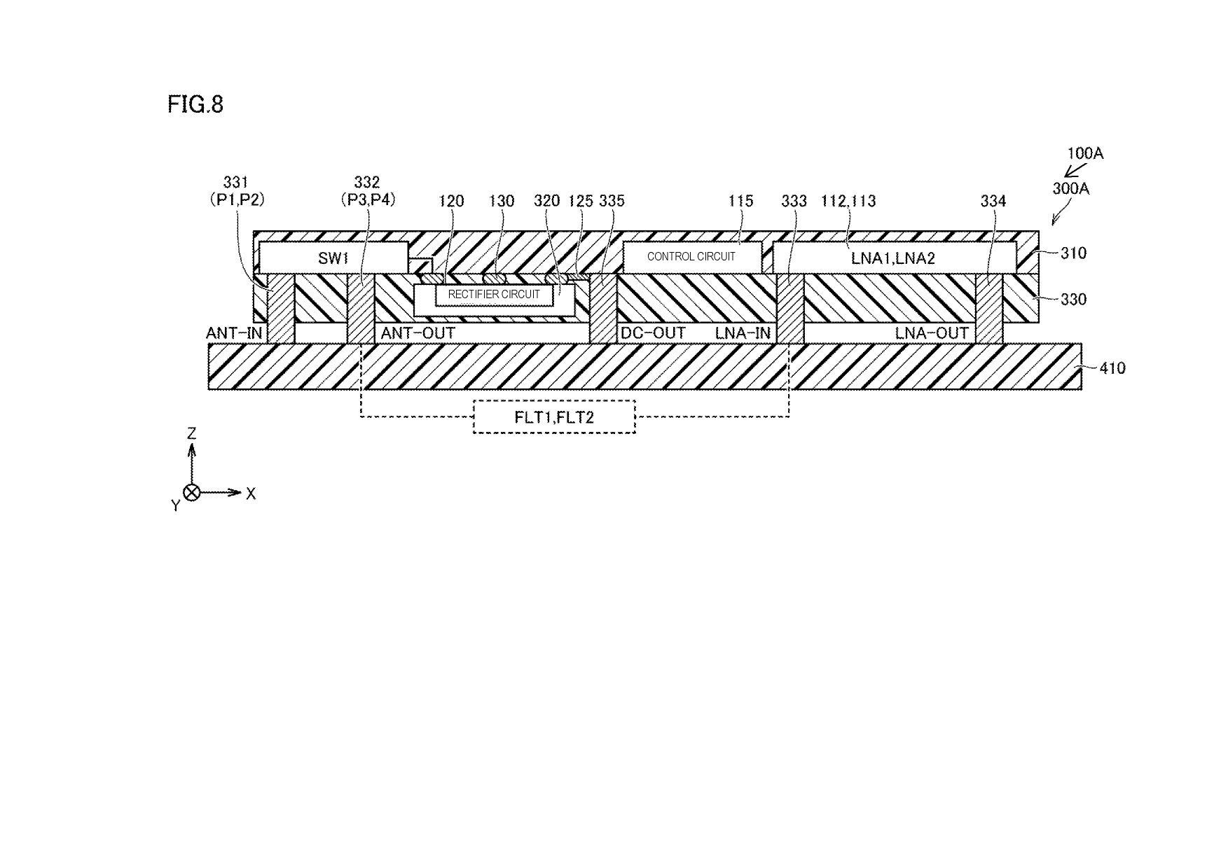

FIG. 8 is a side cutaway view of a substrate 300A where a reception device 100A in a modification is formed. In the substrate 300A, although the basic circuit layout is the same as that in FIG. 3, a position where a rectified DC signal is outputted is different from that in FIG. 3.

Specifically, in the modification, the connection electrode 335 for outputting a DC signal from the rectifier circuit 120 to the outside of the substrate is disposed close to the substrate 320 where the rectifier circuit 120 is disposed. That is, the wiring pattern 125 through which the DC signal is transmitted does not pass between the reception unit 112 and the reception unit 113. Thus, influence of DC power transmitted via the wiring pattern 125 on the reception units 112 and 113 can be further reduced.

### Embodiment 2

In Embodiment 2, another configuration of a distribution circuit that distributes a radio frequency signal from an antenna will be described.

FIG. 9 is an overall block diagram of a communication device 10A in which a reception device 100B according to Embodiment 2 is used. In the reception device 100B illustrated in FIG. 9, the “switch circuit SW”, which is a distribution circuit in the reception device 100 according to Embodiment 1, is replaced with a “power splitter PS”. Except for the above, the configuration of FIG. 9 is the same as that of FIG. 3, and thus descriptions of the same elements will not be repeated.

As in the switch circuit SW, the power splitter PS in the reception device 100B includes the input terminals P1 and P2 and the output terminals P3 to P5. In the power splitter PS, the input terminal P1 is connected to the output terminal P3 and the output terminal P5, and the input terminal P2 is connected to the output terminal P4 and the output terminal P5. In other words, the input terminal P1 is connected to the sub-path SR1 of the path RT1 and the path RT2. Furthermore, the input terminal P2 is also connected to the sub-path SR2 of the path RT1 and the path RT2.

The power splitter PS is a splitter circuit that transmits a received radio frequency signal to both the paths RT1 and RT2, rather than a switch circuit, such as the switch circuit SW according to Embodiment 1, that switches between transmission paths. Thus, in the reception device 100B, information extraction and power extraction from a radio frequency signal can be performed simultaneously. Since a received signal is split into two paths, the received signal level in the RFIC 200 and the charging voltage for charging the battery 230 are lower than those in Embodiment 1, resulting in a longer time period taken to charge. In Embodiment 2, however, the charging process can be performed at all times, and, as a result, in some cases, charging can be performed in a time period equivalent to that in Embodiment 1.

Thus, in the reception device 100B as well, power can be wirelessly received using radio frequency signals (radio waves) used for communication. In addition, only a rectifier circuit portion in the power extraction path is formed of a group III-V compound, and the other circuit portions are formed in an Si-based substrate, thereby enabling an improvement in circuit efficiency while suppressing an increase in cost.

### Aspects

The above-described plurality of exemplary embodiments are understood by those skilled in the art to be specific examples of the following aspects.

(1) A reception device according to an aspect receives a radio frequency signal via an antenna. The reception device includes a first path, a second path, a distribution circuit, a first substrate, and a second substrate disposed on the first substrate. The first path is configured to extract information from a received radio frequency signal. The second path is configured to extract power from a received radio frequency signal. The distribution circuit distributes a received radio frequency signal to the first path and the second path. The first substrate is a semiconductor substrate containing a material primarily composed of an Si-based base material. The second substrate is a semiconductor substrate containing a material primarily composed of a compound of group-III and group-V elements. The first path includes a reception module having an amplifier circuit that amplifies a radio frequency signal. The second path includes a rectifier circuit that rectifies a radio frequency signal. The distribution circuit and the reception module are disposed in the first substrate, and the rectifier circuit is disposed in the second substrate.

(2) In the reception device according to (1), the second path further includes a transmission line through which a radio frequency signal from the distribution circuit is transmitted. The rectifier circuit includes a switching element connected between the transmission line and a ground potential. The switching element has a first terminal connected to the transmission line, a second terminal connected to the ground potential, and a third terminal connected to the second terminal.

(3) In the reception device according to (2), the reception module further includes a first control circuit that controls a bias voltage applied to the transmission line. The first control circuit variably sets a magnitude of the bias voltage in accordance with a received signal level of a radio frequency signal.

(4) In the reception device according to (3), the first control circuit sets the bias voltage to a lower value as the received signal level increases when the received signal level is higher than a predetermined level.

(5) In the reception device according to (2), the reception module includes a second control circuit that controls the amplifier circuit. The second control circuit variably sets a gain of the amplifier circuit in accordance with a received signal level of a radio frequency signal.

(6) In the reception device according to (5), the second control circuit sets the gain of the amplifier circuit to a higher value as the received signal level decreases.

(7) The reception device according to any one of (1) to (6) further includes a filter circuit connected between the distribution circuit and the amplifier circuit.

(8) In the reception device according to (7), the filter circuit is disposed outside the first substrate and the second substrate.

(9) In the reception device according to (2), when the first substrate is viewed in a plan view from a direction normal to the first substrate, a) the distribution circuit is disposed in a first region near a first end portion in the first substrate, b) the amplifier circuit is disposed in a second region near a second end portion facing the first end portion in a first direction in the first substrate, and c) the second substrate is disposed in a region between the first region and the second region.

(10) In the reception device according to (9), the amplifier circuit includes a first amplifier and a second amplifier. When the first substrate is viewed in a plan view from the direction normal to the first substrate, the first amplifier and the second amplifier are disposed so as to be spaced apart from each other in a second direction orthogonal to the first direction, and the transmission line is disposed in a region between the first amplifier and the second amplifier.

(11) In the reception device according to (2), the reception module further includes a first control circuit that controls a bias voltage to the transmission line, and a second control circuit that controls the amplifier circuit. When the first substrate is viewed in a plan view from a direction normal to the first substrate, the second substrate is disposed in a position that does not overlap any of the distribution circuit, the amplifier circuit, the first control circuit, or the second control circuit in the first substrate.

(12) In the reception device according to any one of (1) to (11), the distribution circuit is a switch circuit configured to selectively transmit a radio frequency signal to either the first path or the second path.

(13) In the reception device according to any one of (1) to (11), the distribution circuit is a splitter circuit configured to transmit a radio frequency signal to both the first path and the second path.

(14) A communication device according to an aspect includes the antenna, the reception device according to any one of (1) to (11), a signal processing circuit that processes information extracted in the first path, and a battery that can be charged using power extracted in the second path.

The embodiments disclosed here are illustrative and not restrictive in any respect. The scope of the present disclosure is defined not by the description of the embodiments described above, but by the claims, and is intended to include all changes within the meaning and scope of the claims and their equivalents.

10, 10A communication device, 100, 100A, 100B reception device, 110 reception module, 111 LNA control unit, 112, 113 reception unit, 114 rectifier circuit control unit, 115 control circuit, 120 rectifier circuit, 125 wiring pattern, 130 solder bump, 225 power inductor, 230 battery, 240 power amplifier, 300, 300A, 310, 320 substrate, 330, 420 resin, 331 to 335 connection electrode, 400 communication module, 410 mounting substrate, 430 solder ball, 500 base substrate, ANT, ANT1, ANT2 antenna, C1, C2 capacitor, D drain terminal, FLT1, FLT2 filter, G gate terminal, GND ground potential, L1, L2 inductor, LNA1, LNA2 low noise amplifier, P1, P2 input terminal, P3 to P5 output terminal, PL1 transmission line, PS power splitter, RT1, RT2 path, S source terminal, SR1, SR2 sub-path, SW switch circuit, TR1 transistor

1. A reception device configured to receive a radio frequency signal via an antenna, the reception device comprising:
a first path configured to extract information from a received radio frequency signal;
a second path configured to extract power from the received radio frequency signal;
a distribution circuit configured to distribute the received radio frequency signal to the first path and to the second path;
a first substrate being a semiconductor substrate containing a material primarily composed of an Si-based base material; and
a second substrate being a semiconductor substrate containing a material primarily composed of a compound of group-III and group-V elements,
wherein the first path comprises a reception module comprising an amplifier circuit configured to amplify radio frequency signals,
wherein the second path comprises a rectifier circuit configured to rectify radio frequency signals,
wherein the distribution circuit and the reception module are in the first substrate,
wherein the rectifier circuit is in the second substrate, and
wherein the second substrate is on the first substrate.

2. The reception device according to claim 1,
wherein the second path further comprises a transmission line through which radio frequency signals from the distribution circuit are transmitted,
wherein the rectifier circuit comprises a switch connected between the transmission line and a ground potential, and
wherein the switch has:
a first terminal connected to the transmission line,
a second terminal connected to the ground potential, and
a third terminal connected to the second terminal.

3. The reception device according to claim 2,
wherein the reception module further comprises a first control circuit configured to control a bias voltage applied to the transmission line, and
wherein the first control circuit is configured to variably set a magnitude of the bias voltage in accordance with a received signal level of a radio frequency signal.

4. The reception device according to claim 3, wherein the first control circuit is configured to set the bias voltage to a lower value as the received signal level increases when the received signal level is higher than a predetermined level.

5. The reception device according to claim 2,
wherein the reception module comprises a second control circuit configured to control the amplifier circuit, and
wherein the second control circuit is configured to variably set a gain of the amplifier circuit in accordance with a received signal level of a radio frequency signal.

6. The reception device according to claim 5, wherein the second control circuit is configured to set the gain of the amplifier circuit to a higher value as the received signal level decreases.

7. The reception device according to claim 1, further comprising a filter circuit connected between the distribution circuit and the amplifier circuit.

8. The reception device according to claim 7, wherein the filter circuit is outside the first substrate and the second substrate.

9. The reception device according to claim 2, wherein, when the first substrate is viewed in a plan view from a direction normal to the first substrate:
the distribution circuit is in a first region near a first end portion in the first substrate,
the amplifier circuit is in a second region near a second end portion facing the first end portion in a first direction in the first substrate, and
the second substrate is in a region between the first region and the second region.

10. The reception device according to claim 9,
wherein the amplifier circuit comprises a first amplifier and a second amplifier, and
wherein, when the first substrate is viewed in a plan view from the direction normal to the first substrate:
the first amplifier and the second amplifier are spaced apart from each other in a second direction orthogonal to the first direction, and
the transmission line is in a region between the first amplifier and the second amplifier.

11. The reception device according to claim 2,
wherein the reception module further comprises:
a first control circuit configured to control a bias voltage to the transmission line, and
a second control circuit configured to control the amplifier circuit, and
wherein, when the first substrate is viewed in a plan view from a direction normal to the first substrate, the second substrate does not overlap any of the distribution circuit, the amplifier circuit, the first control circuit, or the second control circuit in the first substrate.

12. The reception device according to claim 1, wherein the distribution circuit is a switch circuit configured to selectively transmit a radio frequency signal to either the first path or the second path.

13. The reception device according to claim 1, wherein the distribution circuit is a splitter circuit configured to transmit a radio frequency signal to both the first path and the second path.

14. A communication device comprising:
the antenna;
the reception device according to claim 1;
a signal processing circuit configured to process information extracted in the first path; and
a battery configured to be charged using power extracted in the second path.
